(19) United States
(12) Patent Application Publication
(10) Pub. No.: US 2024/0320075 A1
(43) Pub. Date: Sep. 26, 2024

(54) SEMICONDUCTOR STORAGE DEVICE AND OPERATING METHOD OF SEMICONDUCTOR STORAGE DEVICE

(71) Applicant: SK hynix Inc., Icheon-si Gyeonggi-do (KR)

(72) Inventor: Jae Yong SON, Icheon-si Gyeonggi-do (KR)

(73) Assignee: SK hynix Inc., Icheon-si Gyeonggi-do (KR)

(21) Appl. No.: 18/462,290

(22) Filed: Sep. 6, 2023

(30) Foreign Application Priority Data
Mar. 21, 2023 (KR) 10-2023-0036637

(51) Int. Cl. G06F 11/07; G11C 16/26

(52) U.S. Cl. CPC G06F 11/076; G11C 16/26

(57) ABSTRACT

A semiconductor storage device searches for an optimal read voltage on the basis of an error bit variance for each second read voltage interval without performing repeated additional reads up to the limit of left and right cell difference probabilities. Accordingly, the semiconductor storage device can detect an optimal read voltage rapidly and accurately by minimizing the number of reads for a memory cell, when performing a second read for determining the optimal read voltage.

### CROSS-REFERENCES TO RELATED APPLICATION

The present application claims priority under 35 U.S.C. § 119(a) to Korean Patent Application No. 10-2023-0036637, filed on Mar. 21, 2023, in the Korean Intellectual Property Office, which is incorporated herein by reference in its entirety.

### BACKGROUND

### 1. Technical Field

The present technology relates to a semiconductor device, and particularly, to a semiconductor storage device that determines an optimal read voltage through a minimum read operation and an operating method of the semiconductor storage device.

### 2. Related Art

A semiconductor storage device may include a volatile memory device or a nonvolatile memory device.

A volatile memory device is a memory device that stores data while power is supplied to the memory device, the data of which is lost when the supply of power to the memory device is blocked. The volatile memory device may include static random-access memory (SRAM) and dynamic random-access memory (DRAM).

A nonvolatile memory device is a memory device in which the state in which data has been stored is maintained although the supply of power to the memory device is blocked. The nonvolatile memory device may include read-only memory (ROM), mask ROM (MROM), programmable ROM (PROM), electrically programmable ROM (EPROM), electrically erasable and programmable ROM (EEPROM), ferromagnetic RAM (FROM), phase change RAM (PRAM), magnetic RAM (MRAM), resistive RAM (RRAM), and flash memory.

Flash memory, that is, an example of the nonvolatile memory used by a nonvolatile memory device, may store 1 bit or two or more multiple bits in one memory cell. If k bits are to be programmed into one memory cell, any one of 2 k threshold voltages is formed in the memory cell. Due to a fine difference between electrical characteristics between memory cells, the threshold voltages of the memory cells into which the same data has been programmed form a threshold voltage distribution having a certain range.

A semiconductor storage device reads data of the memory cells by using one or a plurality of threshold voltages. Accordingly, in order to read data accurately and rapidly, it is necessary to determine an optimal read voltage through a minimum read operation.

### SUMMARY

In an embodiment, a semiconductor storage device may include a memory device including memory cells and a memory controller configured to determine an optimal read voltage for the memory device. The memory controller is configured to select at least three second read voltages in relation to a first read voltage when a first read for the memory device is a fail, obtain second read data by performing a second read using the selected second read voltages, and determine an optimal read voltage based on a minimum error bit variance interval including a minimum error bit variance that is included in the second read data.

In an embodiment, an operating method of a semiconductor storage device may include selecting at least three second read voltages in relation to a first read voltage when a first read for a memory device is a fail, obtaining second read data by using the second read voltages, and determining an optimal read voltage based on a minimum error bit variance interval including a minimum error bit variance that is included in the second read data.

### BRIEF DESCRIPTION OF THE DRAWINGS

FIG. 1 is a construction diagram of a storage device 10 according to an embodiment.

FIG. 2 illustrates an operating method of a semiconductor storage device according to an embodiment.

FIG. 3 illustrates a processing process of a second read step S50 according to an embodiment.

FIG. 4 illustrates a processing process of a first optimal read voltage determination step S551.

FIG. 5 illustrates two error bit variances errv[k] and errv[k+1] at both ends of a minimum error bit variance interval.

FIG. 6 illustrates a processing process of a second optimal read voltage determination step S551a to which a syndrome weight has been applied according to another embodiment.

FIG. 7 illustrates two syndrome weights syndw[k] and syndw[k+1] that are included in a minimum syndrome weight variance interval.

FIG. 8 illustrates a processing process of a third optimal read voltage determination step S552 of determining an optimal read voltage by predicting a minimum error bit variance by quadratic regression.

FIG. 9 illustrates that an optimal read voltage Vop is determined by the step S552 of determining a third optimal read voltage.

FIG. 10 illustrates a processing process of a fourth optimal read voltage determination step S552a of determining an optimal read voltage by calculating a minimum syndrome weight by quadratic regression.

FIG. 11 illustrates that a minimum syndrome weight is calculated by quadratic regression.

FIG. 12 illustrates a processing process of a fifth optimal read voltage determination step S553 of detecting an optimal read voltage by predicting a minimum error bit variance by quadratic regression.

FIG. 13 illustrates that a minimum error bit variance is predicted by applying quadratic regression.

FIG. 14 illustrates a sixth optimal read voltage determination step S553a of determining an optimal read voltage by using a minimum syndrome weight that is predicted by applying quadratic regression.

FIG. 15 illustrates that a minimum syndrome weight is predicted by applying quadratic regression.

### DETAILED DESCRIPTION

In this specification, terms, such as a “first” and a “second,” are used to distinguish one component from another component, and not to imply a number or order of components. The scope of rights of the present technology should not be restricted by the terms.

In this specification, an expression of the singular number includes an expression of the plural number unless clearly defined otherwise in the context. In this specification, a term, such as “include” or “have,” is intended to designate the presence of a described characteristic, number, step, operation, component, part or a combination of them, and should be understood that it does not exclude the possible existence or addition of one or more other characteristics, numbers, steps, operations, components, parts, or combinations of them in advance.

All the terms used in this specification have the same meanings as those that are typically understood by those skilled in the art, unless defined otherwise. Terms, such as ones defined in common dictionaries, should be construed as having the same meanings as those in the context of related technology and are not construed as having ideal or excessively formal meanings, unless clearly defined in the specification.

Terms used in this specification may be defined as follows.

A “first read voltage” may be a hard decision read voltage, that is, a read voltage on which a cell difference probability (CDP) is calculated.

The “CDP” may indicate the degree that a read voltage has deviated from an optimal read voltage of a semiconductor memory device. The “CDP” may mean the asymmetry of parts in which threshold voltage distributions of memory cells are overlapped.

A “first read” may be a data read for a memory device using the first read voltages.

“First read data” may be data that has been read from a memory device by using the first read voltages.

A “second read voltage Vth” may be a soft decision read voltage. The “second read voltage Vth” may be a second read voltage Vth that has been selected to read the second read data based on a CDP that is calculated by the first read voltage.

A “second read” may be a data read for a memory device using the second read voltages Vth.

“Second read data” may be data that has been read from a memory device by using the second read voltages Vth. The “second read data” may be soft decision read data.

An “error bit” may be ones data ones(i). For example, the error bit may include a logic high (1: one).

The “number of error bits” may be the number of error bits that are included in each second read data that has been read by each “second read voltage Vth”. The “number of error bits” may be a ones data count value ones[i].

An “error bit variance errv[i]” may be a difference between the number of error bits that are included in second read data that has been obtained by second read voltages Vth that are adjacent to each other. The “error bit variance errv[i] may be a difference between the number of error bits between an i-th second read voltage Vth(i) and an (i+1)-th second read voltage Vth(i+1), and may indicate a variance of an error bit for each second read voltage interval.

An “error bit variance voltage Verr” may be set as any one of second read voltages Vth corresponding to two error bits, respectively, on which the “error bit variance” has been calculated. When the error bit variance voltage is a smaller one of two second read voltages Vth(i) and Vth(i+i) corresponding to the number of error bits on which the error bit variance has been calculated, an error bit variance voltage Verrv(i) of the i-th error bit variance may be an i-th second read voltage Vth(i). When the error bit variance voltage is a greater one of two second read voltages corresponding to the number of error bits on which the error bit variance has been calculated, an error bit variance voltage Verrv(i+1) of an i-th error bit variance may be an (i+1)-th second read voltage Vth(i+i).

A “minimum error bit variance interval” may include an interval in which the error bit variance is decreased and increased. The “minimum error bit variance interval” may include a minimum error bit variance.

A “minimum syndrome weight variance interval” may include an interval in which a syndrome weight is decreased and increased. A “minimum syndrome weight variance interval” may include a minimum syndrome weight.

A “syndrome voltage Vsynd(i)” may be second read voltage Vth(i) that has been obtained by reading second read data on which a syndrome has been calculated.

A “second read voltage interval Vint” may be a voltage interval between second read voltages Vth. Vint(i) may indicate an i-th second read voltage interval. The i-th second read voltage interval Vint(i) may be a voltage interval between an i-th second read voltage Vth(i) and an (i+1)-th second read voltage Vth(i+1).

Hereinafter, embodiments are described with reference to the accompanying drawings.

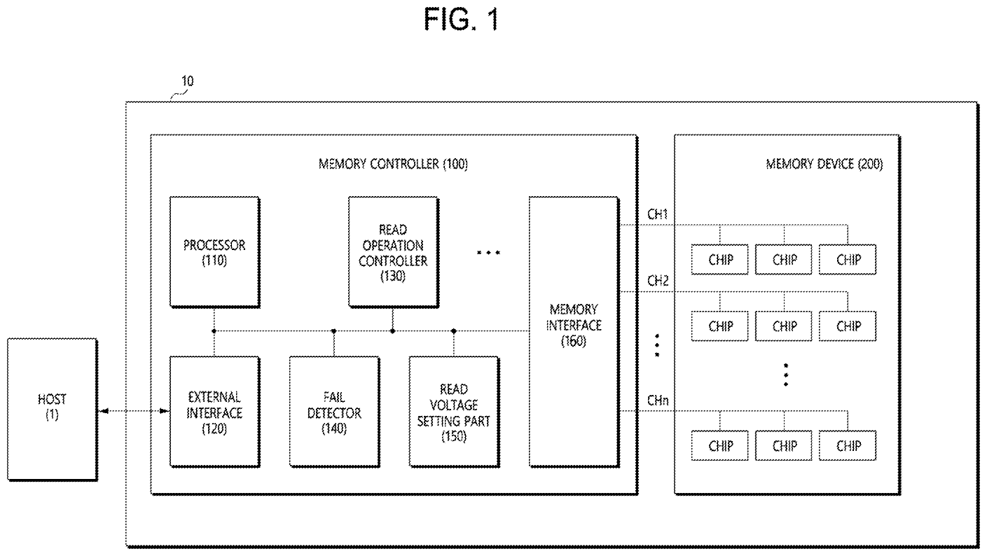

FIG. 1 may be a construction diagram of a semiconductor storage device 10 according to an embodiment.

The semiconductor storage device 10 may communicate with an external device 1. The external device 1 may be a device that transmits and receives signals and data to and from the semiconductor storage device 10. The semiconductor storage device 10 may be manufactured as one of various types of storage devices depending on an external interface that provides a method for communication with the external device 1.

The semiconductor storage device 10 may include a memory controller 100 and a memory device 200.

The memory controller 100 may calculate an error bit variance from second read data that has been obtained by a second read using a second read voltage Vth.

The memory controller 100 may calculate, for each second read voltage, the number of error bits that are included in the second read data that has been by the second read using the second read voltage Vth.

The memory controller 100 may calculate a difference between the numbers of error bits for each second read voltage Vth. The difference between the numbers of error bits for each second read voltage Vth is an error bit variance errv[i]. The error bit variance errv[i] may be applied by being substituted with a syndrome weight syndw[i] of a syndrome.

The memory controller 100 may determine an optimal read voltage using error bit variances at both ends of a minimum error bit variance interval. The memory controller 100 may determine an optimal read voltage by predicting a minimum error bit variance within a minimum error bit variance interval.

The minimum error bit variance interval may be an error bit variance interval that is defined by two second read voltages, in which the error bit variance is decreased and increased.

The memory device 200 may include memory cells.

The memory device 200 may include at least one of a volatile memory device and a nonvolatile memory device.

The memory device 200 may be connected to the memory controller 100 through a plurality of channels CH1 to CHn.

The memory device 200 may include a plurality of memory chips CHIP or a plurality of packages.

In an embodiment, an example in which the memory device 200 is NAND flash memory is described, for convenience of description.

The memory device 200 may be configured to receive a command and an address from the memory controller 100 and to access an area of a memory cell array, which is selected by the received address. The memory device 200 may perform a program operation, a read operation, and an erase operation on the area selected by the received address.

After the start of the program operation, the memory device 200 may program data into the area selected by the address.

The read operation may include a first read, a second read, and an optimal read voltage read. After the start of the read operation, the memory device 200 may read data from the area selected by the received address. The memory device 200 may read data from memory cells by using an optimal read voltage that is set in the memory controller 100.

After the start of the erase operation, the memory device 200 may erase data that has been stored in the area selected by the received address.

The memory device 200 may operate in response to control by the memory controller 100.

The memory controller 100 may control an overall operation of the semiconductor storage device 10.

In an embodiment, the memory controller 100 may receive data and a logical block address (LBA) from the external device 1. The memory controller 100 may convert the received LBA into a physical block address (PBA) of memory cells that are included in the memory device 200.

The memory controller 100 may control the memory device 200 so that the memory device 200 performs a program operation, a read operation, or an erase operation in response to a request from the external device 1. After the start of the program operation, the memory controller 100 may provide a program command, a PBA, and data to the memory device 200. After the start of the read operation, the memory controller 100 may provide a read command and a PBA to the memory device 200. After the start of the erase operation, the memory controller 100 may provide an erase command and a PBA to the memory device 200.

The memory controller 100 may autonomously generate a program command, an address, and data regardless of a request from the external device 1, and may transmit the program command, address, and data to the memory device 200. For example, the memory controller 100 may provide the memory device 200 with a command, an address, and data for performing background operations. The memory controller 100 may control at least two of the memory devices 200.

The memory controller 100 may include a processor 110, an external interface 120, a read operation controller 130, a fail detector 140, a read voltage setting part 150, and a memory interface 160.

The processor 110 may control an operation of the semiconductor storage device 10. The operation of the semiconductor storage device 10 may include a data read, a data program, data erase, the management of a background operation, or communication with the outside.

The processor 110 may have a form in which hardware and firmware or software that operates on the hardware have been combined.

When power is applied to the semiconductor storage device 10, the memory controller 100 may execute firmware (FW) for controlling communication between the external device 1 and the memory device 200. The firmware may include an external device controller (HIL Control Top (HCT)) and a flash translation layer (FTL).

The external interface 120 may receive a command and a clock signal from the external device 1 under the control of the processor 110, and may provide a communication channel for controlling the input and output of data to and from the external device 1. The external interface 120 may provide a communication connection for communication between the external device 1 and the semiconductor storage device 10.

The read operation controller 130 may control a read operation for memory cells that are included in the memory device 200. The read operation controller 130 may provide the memory device 200 with a read command and an address of memory cells to be read. The read operation controller 130 may perform an operation for changing a read voltage before providing the read command to the memory device 200.

The read operation controller 130 may control a first read for the memory device 200 to read memory cells by using first read voltages. The first read voltage may be a hard decision read voltage.

The read operation controller 130 may obtain first read data that has been read from memory cells by using the first read voltages.

When the first read fails, the read operation controller 130 may control a second read to read the memory cells by using a plurality of second read voltages. The plurality of second read voltages may be determined based on the first read voltage that has failed. The at least three second read voltages Vth may be selected on the basis of the first read voltage.

The read operation controller 130 may obtain second read data by performing the second read using the second read voltages Vth that have been selected.

The read operation controller 130 may control an optimal read voltage read based on an optimal read voltage. The optimal read voltage may be determined by using a minimum error bit variance interval. The read operation controller 130 may obtain optimal read voltage read data by performing an optimal read voltage read using an optimal read voltage.

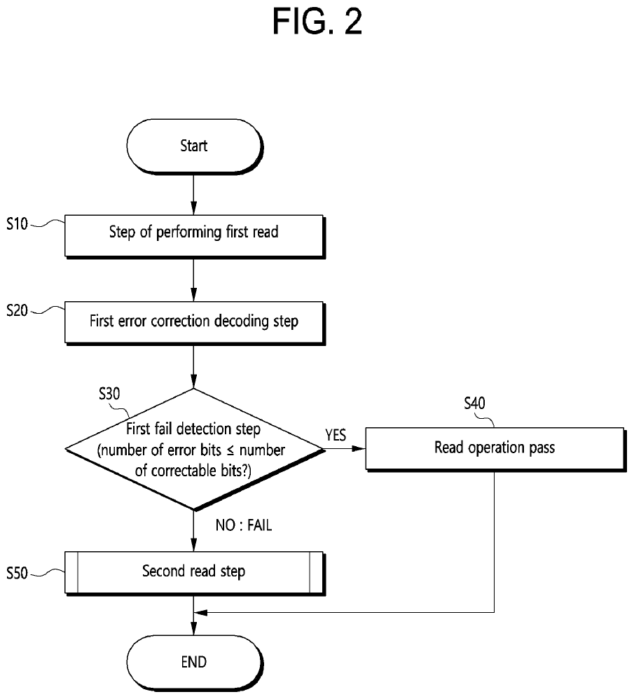

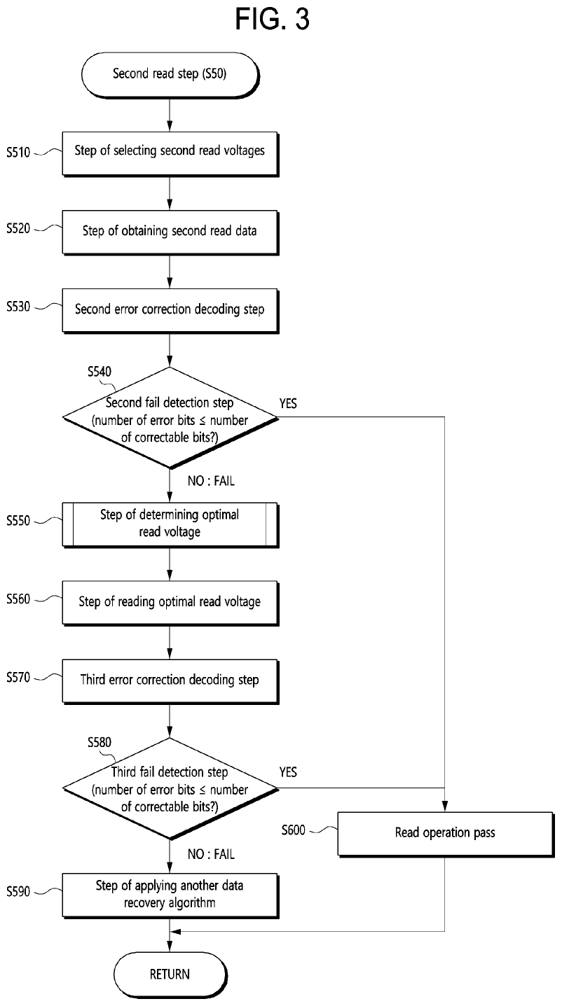

The fail detector 140 may determine the fail or pass of the first read by performing first error correction decoding on the first read data (S20 and S30, refer to FIG. 2). The fail detector 140 may determine the fail or pass of the second read by performing second error correction decoding on the second read data (S530 and S540, refer to FIG. 3). The fail detector 140 may determine the fail or pass of the optimal read voltage read by performing third error correction decoding on the optimal read voltage read data (S560 and S580, refer to FIG. 3).

When the number of error bits that are included in read data is equal to or smaller than the number of bits capable of being corrected by an error correction decoder, each of the first read, the second read, and the optimal read voltage read may be a pass.

When the number of error bits that are included in read data is greater than the number of bits capable of being corrected by the error correction decoder, each of the first read, the second read, and the optimal read voltage read may be a fail.

The number of error bits may be the number of memory cells each of which must be read as an on cell, but is read as an off cell or each of which must be read as an off cell, but is read as an on cell, depending on the state in which each memory cell has been programmed.

The number of bits that are correctable may be the number of error bits which may be recovered to original bits by the error correction decoder.

When the first read, the second read, or the optimal read voltage read is a pass, original data may be recovered.

When the first read, the second read, or the optimal read voltage read fails, the original data might not be recovered.

The read voltage setting part 150 may set first read voltages for the first read. The read voltage setting part 150 may set a plurality of second read voltages when the first read fails.

The read voltage setting part 150 may calculate an optimal read voltage when second error correction decoding for the second read data fails in the fail detector 140.

When the second read fails, the read voltage setting part 150 may predict a minimum error bit variance that is included in the second read data, and may determine an error bit variance voltage corresponding to the minimum error bit variance as an optimal read voltage.

The read voltage setting part 150 may calculate the number of error bits for each second read voltage Vth. The number of error bits may be ones data count value ones[i], ones[i+1], . . . , which have been accumulated up to the second read voltage Vth. The ones data count value may be the number of memory cells in each of which data accumulated for each second read voltage Vth has “1”.

The read voltage setting part 150 may calculate an error bit variance by applying the second read voltage and the number of error bits.

The error bit variance may be a ones data count value of each of second read voltage intervals Verr. The error bit variance errv[i] may be a difference between ones data of the second read voltages Vth(i) and Vth(i+1) on both sides of each second read voltage interval Verrv(i).

The error bit variance errv[i] of an i-th second read voltage interval Verrv(i), among the error bit variances, may be a value obtained by subtracting an accumulated ones data count value ones[i]) up to an i-th second read voltage Vth(i) from an accumulated ones data count value ones[i+1] up to an (i+1)-th second read voltage Vth(i+1).

The read voltage setting part 150 may calculate the number of error bits for each second read voltage Vth(i), which are included in the second read data. The read voltage setting part 250 may calculate the error bit variance errv[i] for each second read voltage interval Vint(i) by calculating a difference between the number of error bits for each second read voltage Vth and the number of error bits for each second read voltage Vth, which are adjacent to each other.

The read voltage setting part 150 may detect a minimum error bit variance interval in which the error bit variance errv[i] is decreased and increased. The minimum error bit variance interval may include an error bit variance errv[k] that is more decreased than a previous error bit variance errv[k−1] and an error bit variance errv[k+1] that is more increased than the error bit variance errv[k].

If the minimum error bit variance interval is not present, the read voltage setting part 150 may control the read operation controller 130 to perform one additional read. The read voltage setting part 150 may set, as an additional read voltage, a first read voltage that is most adjacent in a direction in which the error bit variance is decreased, and may transmit the first read voltage to the read operation controller 130.

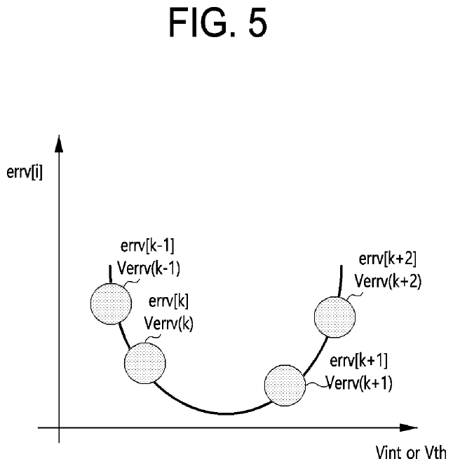

The read operation controller 130 may calculate an additional error bit variance errv[i+2] (refer to FIG. 5) by performing an additional read using the additional read voltage.

The setting of the first additional read voltage by the read voltage setting part 150 and a first additional read operation by the read operation controller 130 may be repeatedly performed until the minimum error bit variance interval is detected. The additional read may be performed within the range of the cell difference probability (CDP).

The read voltage setting part 150 may determine again whether the minimum error bit variance interval is present after performing the one first additional read.

When the minimum error bit variance interval is detected, the read voltage setting part 150 may determine an optimal read voltage by using error bit variances at both ends of the minimum error bit variance interval.

The read voltage setting part 150 may detect the error bit variance voltage Verrv[k] of two error bit variances errv[k] and errv[k+1] at both ends of the minimum error bit variance interval. One of two second read voltages Vth(k) and Vth(k+1) corresponding to the number of error bits the error bit variance errv[k] of which has been calculated may be selected as the error bit variance voltage Verrv[k].

When the error bit variance voltage Verrv(i) is a lower voltage among the two second read voltages, the error bit variance voltage Verrv(i) of an i-th error bit variance errv[i] may be an i-th second read voltage Vth(i). When the error bit variance voltage Verrv(i) is a higher voltage among the two second read voltages Vth(i) and Vth(i+1), the error bit variance voltage Verrv(i) of the i-th error bit variance errv[i] may be an (i+1)-th second read voltage Vth(i+1).

The read voltage setting part 150 may set an averaged voltage of the two error bit variance voltages Verrv[k] and Verrv[k+1] as the optimal read voltage.

In order to increase the accuracy of the optimal read voltage, the read voltage setting part 150 may determine the optimal read voltage by performing quadratic regression using three error bit variances.

The three error bit variances may include the two error bit variances errv[k] and errv[k+1] at both ends of the minimum error bit variance interval and an added one additional error bit variance errv[k+2] (refer to FIG. 5).

The read voltage setting part 150 may select two error bit variance voltages that are adjacent to each other on both sides of the minimum error bit variance interval, that is, a (k−1)-th error bit variance voltage Verrv[k−1] and a (k+2)-th error bit variance voltage Verrv(k+2). The (k−1)-th error bit variance voltage Verrv[k−1] may be any one of a (k−1)-th second read voltage Vth(k−1) and a k-th second read voltage Vth(k). The (k+2)-th error bit variance voltage Verrv(k+2) may be any one of a (k+2)-th second read voltage Vth(k+2) and a (k+3)-th second read voltage Vth(k+3). Each of the (k+2)-th error bit variance voltage Verrv(k+2) and the (k−1)-th error bit variance voltage Verrv[k−1] may be identically set as a second read voltage on a higher side or a second read voltage on a lower side.

The read voltage setting part 150 may calculate error bit variances errv[k−1] and errv[k+2] of each of the two error bit variance voltages Verrv[k−1] and Verrv(k+2).

The read voltage setting part 150 may calculate a difference (i.e., a difference between first error bit variances) between the error bit variance errv[k−1] and an error bit variance errv[k] that is consecutive to the error bit variance errv[k−1]. The read voltage setting part 150 may calculate a difference (i.e., a difference between second error bit variances) between the error bit variance errv[k+1] and the error bit variance errv[k+2] that is consecutive to the error bit variance errv[k+1].

The read voltage setting part 150 may set, as a second additional read voltage, an error bit variance voltage corresponding to a lower side in the difference between the first and second error bit variances. In an embodiment, it is described that the (k+2)-th error bit variance voltage Verrv(k+2) has been selected as the second additional read voltage.

The read voltage setting part 150 may obtain additional read data by performing an additional read using the selected additional read voltage Verrv(k+2).

The read voltage setting part 150 may calculate the number of additional error bits from the additional read data.

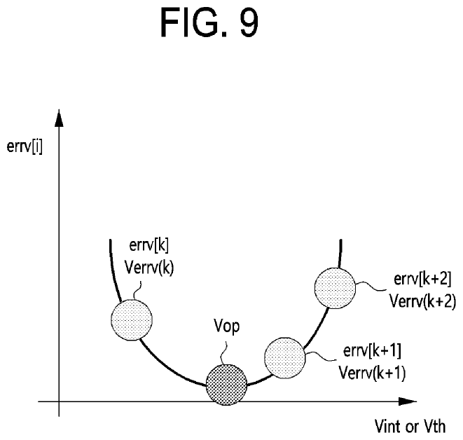

The read voltage setting part 150 may generate the additional error bit variance errv[k+2] (refer to FIG. 9) by calculating a difference between the calculated number of additional error bits and the number of error bits of a second read voltage Verrv[k+1] (refer to FIG. 9) that is adjacent within the minimum error bit variance interval.

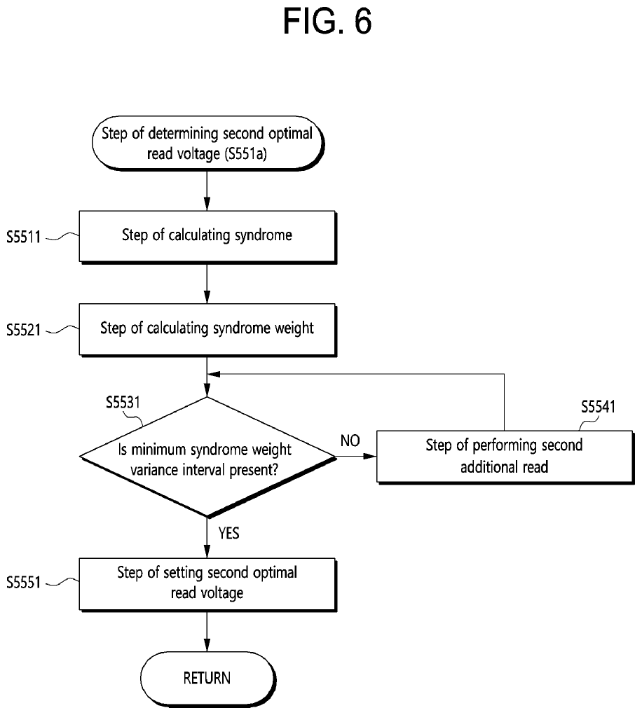

In another embodiment, an optimal read voltage may be set by calculating a syndrome synd(i) for the second read data (refer to FIGS. 6, 7, 10, 11 14, and 15).

In this case, the number of error bits may be substituted with a syndrome that has been calculated with respect to the second read data. The error bit variance errv may be substituted with a syndrome weight syndw[i] of the second read data that has been obtained for each second read voltage Vth.

The syndrome may be generated by an operation of a parity check matrix and the second read data when error correction decoding is performed on the second read data. The syndrome may correspond to an error pattern including the location of an error of the second read data. The size of the syndrome may be indicated as a syndrome weight syndw. The syndrome weight syndw[i] may be the number of “1s” that are included in a syndrome synd(i) for second read data that has been obtained for each second read voltage Vth. The number of “1s” that are included in the syndrome synd(i) may be the number of error bits. When the syndrome weight syndw[i] is 0, it may be determined that data does not include an error bit.

When the syndrome weight syndw[i] is not 0, data may include an error bit.

The smaller the syndrome weight syndw[i], the smaller the number of error bits that are included in data. The greater the syndrome weight syndw[i], the greater the number of error bits that are included in data. When the number of error bits is equal to or smaller than the number of error bits that are correctable, error correction decoding may be a pass. When the number of error bits is greater than the number of error bits that are correctable, error correction decoding may be a fail.

An interval including a minimum syndrome weight syndw[i] is a minimum syndrome weight variance interval. The minimum syndrome weight variance interval may include a syndrome weight syndw[k] smaller than a previous syndrome weight syndw[k−1] and a syndrome weight syndw[k+1] greater than the syndrome weight syndw[k]. The two syndrome weights syndw[k] and syndw[k+1] are continuous to each other. A minimum syndrome weight is present between the two syndrome weights syndw[k] and syndw[k+1].

The read voltage setting part 150 may determine, as an optimal read voltage Vop, a voltage corresponding to a syndrome that has a minimum syndrome weight.

The read voltage setting part 150 may calculate a syndrome synd(i) and a syndrome weight syndw[i] for each of the second read data.

The read voltage setting part 150 may detect, as the minimum syndrome weight variance interval, an interval in which the syndrome weight syndw[i] is decreased and increased. The minimum syndrome weight variance interval may be an interval that is limited to a syndrome weight syndw[k] smaller than a previous syndrome weight syndw[k−1] and a syndrome weight syndw[k+1] greater than a syndrome weight syndw[k].

If the minimum syndrome weight variance interval is not detected, the read voltage setting part 150 may set, as a second additional read voltage Vsynd(k+2), a second read voltage in a direction in which the variance of the syndrome weight is decreased. The read operation controller 130 may calculate an additional syndrome and an additional syndrome weight syndw[k+2] by a second additional read using a second additional read voltage Vsynd(k+2). Thereafter, the read voltage setting part 150 may detect the minimum syndrome weight variance interval by using an added syndrome weight syndw[k+2].

The setting of the additional read voltage by the read voltage setting part 150 and the additional read of the read operation controller 130 may be repeatedly performed until the minimum syndrome weight variance interval is detected. The additional read may also be performed within the range of the CDP.

When the minimum syndrome weight variance interval is detected, the read voltage setting part 150 may calculate two second read voltages Vth(k) and Vth(k+1) corresponding to two syndrome weights syndw(k) and syndw(k+1) that are included in the minimum syndrome weight variance interval. The read voltage setting part 150 may set an averaged voltage of the calculated two second read voltages Vth(k) and Vth(k+1) as the optimal read voltage Vop.

In order to increase the accuracy of the optimal read voltage, the read voltage setting part 150 may determine the optimal read voltage by quadratic regression for three syndrome weights.

The three syndrome weights may include two syndrome weights syndw(k) and syndw(k+1) at both ends of the minimum syndrome weight variance interval and an added one additional syndrome weight syndw(k+2). The additional syndrome weight syndw[k+2] may be a syndrome weight having a smaller variance, among syndrome weights that are disposed at both ends of the minimum syndrome weight variance interval outside the minimum syndrome weight variance interval. The additional syndrome weight may be syndw(k−1).

The quadratic regression for the three syndrome weights may be performed as follows.

The read voltage setting part 150 may derive a quadratic function for the three syndrome weights syndw[k], syndw[k+1], and syndw[k+2]. The read voltage setting part 150 may search the quadratic function for a minimum syndrome weight corresponding to a minimum point. The read voltage setting part 150 may set, as the optimal read voltage, a syndrome voltage corresponding to the minimum syndrome weight.

The memory interface 160 may be configured to communicate with the memory device 200 under the control of the processor 110. The memory interface 160 may provide a communication channel for the transmission and reception of signals between the memory controller 100 and the memory device 200. The memory interface 160 may transmit and receive internal commands, addresses, and data to and from the memory device 200 through the channel. The memory interface 160 may store, in the memory device 200, data that has been temporarily stored in buffer memory (not illustrated) under the control of the processor 110. The memory interface 160 may temporarily store data that has been read from the memory device 200 by transferring the data to the buffer memory. The memory interface 160 may further include the error correction decoder (not illustrated). The error correction decoder may perform error correction encoding (e.g., ECC encoding) based on data that is output to the memory device 200 through the memory interface 160 after the start of a program operation. The error correction-encoded data may be transferred to the memory device 200 through the memory interface 160.

FIG. 2 illustrates an operating method of the semiconductor storage device 10 according to an embodiment.

As in FIG. 2, the operating method of the semiconductor storage device according to an embodiment may include a step S10 of performing a first read, a first error correction decoding step S20, a first fail detection step S30, and a step S50 of performing a second read.

The operating method of the semiconductor storage device according to an embodiment may further include a step S40 of passing a read operation when the first read is determined to be a fail in the first fail detection step S30.

The step S10 of performing the first read is a step of reading, by the read operation controller 130, memory cells by using first read voltages. The first read voltages may be voltages that have been previously set in order to distinguish between memory cells in any one of an erase state and a plurality of program states. The first read voltage may be a threshold voltage that has been set to read data of memory cells.

The memory cell may have a threshold voltage within a certain range based on a value of data that is stored through a program. A memory cell in which data “1” is stored may have a threshold voltage lower than a first read voltage. A memory cell in which data “0” is stored may have a threshold voltage higher than the first read voltage.

In the first read, “1” (one) or “0” (zero) may be read based on a current that is formed in a single bit memory cell as the memory cell is turned on/off when the first read voltage is applied to the memory cell, for example. A memory cell having a threshold voltage lower than the first read voltage may be turned on in response to the first read voltage, and data “1” may be read from the memory cell. A memory cell having a threshold voltage higher than the first read voltage may be turned off in response to the first read voltage, and data “0” may be read from the memory cell.

The threshold voltages of the memory cell may be overlapped. The overlapping of the threshold voltages may occur because the threshold voltages of memory cells in which data “1” is stored rise and thus a distribution of the threshold voltages of the memory cells in which the data “1” is stored moves to the right. The overlapping of the threshold voltages may occur because the threshold voltages of memory cells in which data “0” is stored fall and thus a distribution of the threshold voltages of the memory cells in which the data “0” is stored moves to the left. If a distribution of the threshold voltages of the memory cells in which the data “0” has been stored moves to the left (i.e., a lower voltage side) of the first read voltage, data “1” may be read from the memory cell in which the data “0” has been stored when a first read is performed.

The first error correction decoding step S20 may be a step of correcting, by the memory controller 100, an error that is included in the first read data. The first error correction decoding step S20 may be performed by using an error correcting code (ECC).

The first fail detection step S30 may be a step of determining, by the fail detector 140, the pass or fail of the first read. When the fail detector 140 recovers original data through the first error correction decoding step S20, the first read may be a pass. If the fail detector 140 does not recover the original data through the first error correction decoding step S20, the first read may be a fail.

When the first error correction decoding is a fail in the first fail detection step S30, the read operation controller 130 may perform the second read step S50.

The second read step S50 may be a step of reading, by the read operation controller 130, the memory cells by using a plurality of second read voltages Vth.

FIG. 3 illustrates a processing process of the second read step S50 according to an embodiment.

In an embodiment, the second read step S50 may include a step S510 of selecting second read voltages Vth, a step S520 of obtaining second read data, a second error correction decoding step S530, a second fail detection step S540, a step S550 of determining an optimal read voltage, a step S560 of reading an optimal read voltage, a third error correction decoding step S570, and a third fail detection step S580.

The second read step S50 may further include another data recovery algorithm application step S590 of performing a read operation by applying another data recovery algorithm when the second read is a fail in the third fail detection step S580.

The step S510 of selecting second read voltages Vth may be a step of determining the second read voltages Vth based on the first read voltage. The second read voltage Vth may be determined based on reliability information of the first read data that has been read by using the first read voltage. The reliability information may be information with regard to the probability that the first read data will be an error bit. The reliability information of the first read data may be a log likelihood ratio (LLR). That is, each of the second read voltages Vth may be set to have a voltage value having a low probability that the first read data will be an error bit. The first read voltage may be a distribution of the threshold voltage of memory cells. The second read voltages Vth may be set in a plural number for each threshold voltage distribution. In the step S510 of selecting the second read voltages, at least three second read voltages Vth may be selected. In order to obtain the minimum error bit variance interval or the minimum syndrome weight variance interval, at least three second read voltages Vth may be required.

The step S520 of obtaining second read data may be a step of obtaining, by the read operation controller 130, the second read data by reading the memory cells by using the plurality of second read voltages Vth.

The second error correction decoding step S530 may be a step of correcting, by the error correction decoder, an error included in the second read data that has been obtained by the plurality of second reads by performing soft decision decoding.

The second fail detection step S540 may be a step of determining the pass or fail of the second reads. The second reads may be a fail when the number of error bits included in the second read data is greater than the number of bits capable of being recovered by the error correction decoder. The second reads may be a pass when the number of error bits included in the second read data is not greater than the number of bits capable of being recovered by the error correction decoder.

The step S550 of determining an optimal read voltage may be performed by the read voltage setting part 150 when the second reads are a fail in the second fail detection step S540. The step S550 of determining an optimal read voltage may be a step of determining, by the read voltage setting part 150, a voltage having a minimum error bit variance for each second read voltage Vth as the optimal read voltage.

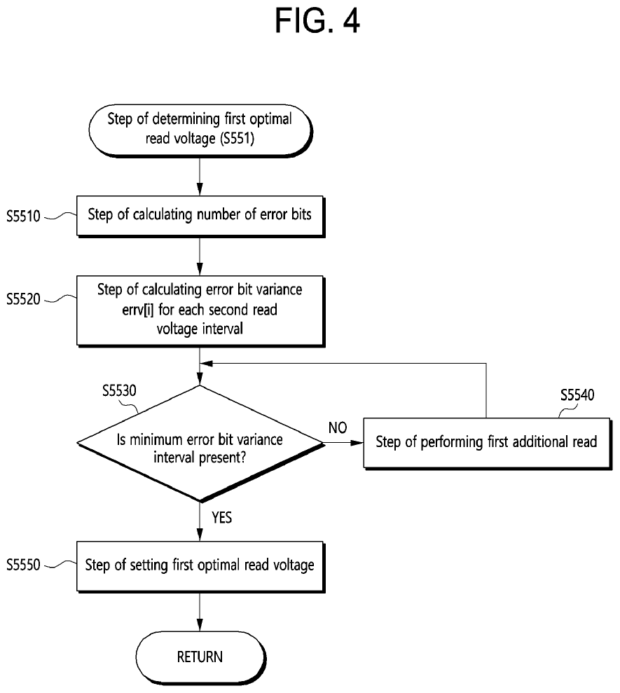

The step S550 of determining an optimal read voltage is described in more detail with reference to FIGS. 4 to 9.

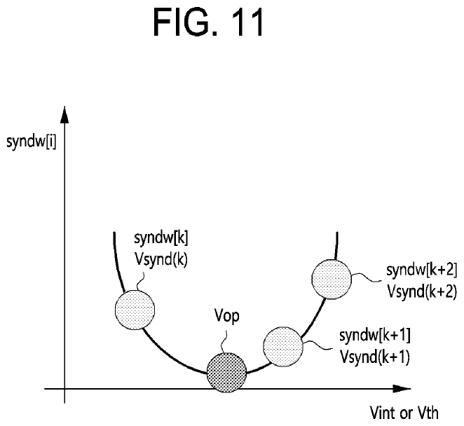

The step S560 of reading an optimal read voltage may be a step of reading, by the read operation controller 130, data of the memory cells by using the determined optimal read voltage Vop (refer to FIGS. 9 and 11).

The third error correction decoding step S570 may be a step of recovering, by the error correction decoder, an error included in the optimal read voltage read data that has been read by using the optimal read voltage Vop.

The third fail detection step S580 may be a step of determining, by the fail detector 140, the pass or fail of the optimal read voltage read. The optimal read voltage read may be a pass when the number of error bits included in the optimal read voltage read data is equal to or smaller than the number of bits capable of being corrected by the error correction decoder. The optimal read voltage read may be a fail when the number of error bits included in the optimal read voltage read data is greater than the number of bits capable of being corrected by the error correction decoder.

The another data recovery algorithm application step S590 may be a step of performing, by the read operation controller 130, a read operation by applying another data recovery algorithm when the optimal read voltage read is a fail in the third fail detection step S580.

A step S600 of passing a read operation in FIG. 3 may be a step of passing the second read operation when the second read is a pass in the second fail detection step S540. This means that the second read voltage that has been read from the second read data is an optimal read voltage.

A step S551 of determining a first optimal read voltage by applying an error bit variance is described.

FIG. 4 illustrates a processing process of the step S551 of determining a first optimal read voltage by applying an error bit variance. FIG. 5 illustrates two error bit variances errv[k] and errv[k+1] at both ends of a minimum error bit variance interval.

In FIG. 5, an interval that is limited to the two error bit variances errv[k] and errv[k+1] may be the minimum error bit variance interval. The errv[k] and errv[k+1] may indicate k-th and (k+1)-th error bit variances, respectively.

In FIG. 5, Verrv[k] may be a k-th error bit variance voltage. The Verrv[k] may be any one of a k-th second read voltage Vth(i) or a (k+1)-th second read voltage Vth(k+1). In FIG. 5, Verrv[k+1] may be a (k+1)-th error bit variance voltage. The Verrv[k+1] may be any one of a (k+1)-th second read voltage Vth(k+1) or a (k+2)-th second read voltage Vth(k+2).

The step S551 of determining a first optimal read voltage by applying an error bit variance may be a step of determining, by the read voltage setting part 150, an optimal read voltage by using the minimum error bit variance interval.

The read voltage setting part 150 may calculate the two error bit variance voltages Verrv[k] and Verrv[k+1] from the two error bit variances errv[k] and errv[k+1] at both ends of the minimum error bit variance interval. The read voltage setting part 150 may set an averaged voltage of the calculated two error bit variance voltages Verrv[k] and Verrv[k+1] as the optimal read voltage Vop.

As in FIG. 4, the step S551 of determining a first optimal read voltage may include a step S5510 of calculating the number of error bits, a step S5520 of calculating an error bit variance, a step S5530 of determining whether a minimum error bit variance interval is present, a step S5540 of performing a first additional read, and a step S5550 of setting a first optimal read voltage.

The step S5510 of calculating the number of error bits may be a step of calculating, by the read voltage setting part 150, the number of error bits included in second read data that has been read by using each second read voltage based on the second read data.

The step S5520 of calculating an error bit variance may be a step of calculating, by the read voltage setting part 150, an error bit variance errv[i], that is, a difference between the number of error bits between two second read voltages adjacent to each other, that is, the second read voltages Vth[i] and Vth[i+1].

The step S5530 of determining whether a minimum error bit variance interval is present may be a step of determining, by the read voltage setting part 150, whether the error bit variances errv[i] have a minimum error bit variance interval.

The minimum error bit variance interval may include two consecutive error bit variances including a minimum error bit variance.

The two consecutive error bit variances may include the error bit variance errv[k] that is more reduced than a previous error bit variance errv[k−1] and the error bit variance errv[k+1] that is more increased than the error bit variance errv[k]. The two consecutive error bit variances may be disposed at both ends of the minimum error bit variance interval.

The error bit variance errv may be changed in a two-dimensional parabolic form for a second read voltage or the number of error bits (refer to FIG. 5). The reason for this is that an error bit variance errv[i] is decreased as a second read voltage Vth becomes adjacent to an optimal read voltage Vop, and the error bit variance errv[i] is increased as the second read voltage Vth becomes distant from the optimal read voltage Vop. The step S5540 of performing a first additional read may be performed if a minimum error bit variance interval is not present as the results of performing the step S5530 of determining whether a minimum error bit variance interval is present.

In the step S5540 of performing a first additional read, the read voltage setting part 150 may select two second read voltages Vth adjacent to the minimum error bit variance interval as first additional read voltages. The two second read voltages may include a (k−1)-th second read voltage Vth(k−1) and a (k+2)-th second read voltage Vth(k+2). The two second read voltages Vth(k−1) and Vth(k+2) may be error bit variance voltages Verrv[k−1] and Verrv(k+2), respectively.

The read operation controller 130 may add second read data by performing an additional read using the selected two second read voltages Vth(k−1) and Vth(k+2).

The read voltage setting part 150 may calculate error bit variances errv[k−1] and errv(k+2) of the two second read voltages Vth(k−1) and Vth(k+2), respectively, which have been selected from the second read data.

The read voltage setting part 150 may calculate a first error bit variance difference between the calculated error bit variance errv[k−1] and the error bit variance errv[k] adjacent to the error bit variance errv[k−1]. The read voltage setting part 150 may calculate a second error bit variance difference between a calculated error bit variance errv(k+2) and an error bit variance errv[k+1] adjacent to the error bit variance errv(k+2). The read voltage setting part 150 may select an error bit variance having a smaller value as an additional error bit variance errv[k+2] by comparing the first error bit variance difference and the second error bit variance difference.

After the step S5540 of performing a first additional read is performed, the process may return to the step S5530 of determining whether a minimum error bit variance interval is present. The read voltage setting part 150 may determine whether a minimum error bit variance interval is present again, including the additional error bit variance.

The read voltage setting part 150 may perform the step S5550 of setting a first optimal read voltage when the minimum error bit variance interval is present. In FIG. 5, the minimum error bit variance interval may be an interval between the error bit variances errv[k] and errv[k+1].

However, if the minimum error bit variance interval is not present, the read voltage setting part 150 may control the read operation controller 130 to perform the process again from the step S5540 of performing a first additional read.

The step S5550 of setting a first optimal read voltage may be performed when the minimum error bit variance interval is present. In FIG. 5, the minimum error bit variance interval may be an interval between the error bit variances errv[k] and errv[k+1].

The step S5550 of setting a first optimal read voltage may be a step of determining, by the read voltage setting part 150, an optimal read voltage based on the minimum error bit variance interval.

The read voltage setting part 150 may calculate the two error bit variance voltages Verrv[k] and Verrv[k+1] corresponding to the two error bit variances errv[k] and errv[k+1] at both ends of the minimum error bit variance interval, respectively. The read voltage setting part 150 may set an averaged voltage of the calculated two error bit variance voltages Verrv[k] and Verrv[k+1] as the optimal read voltage.

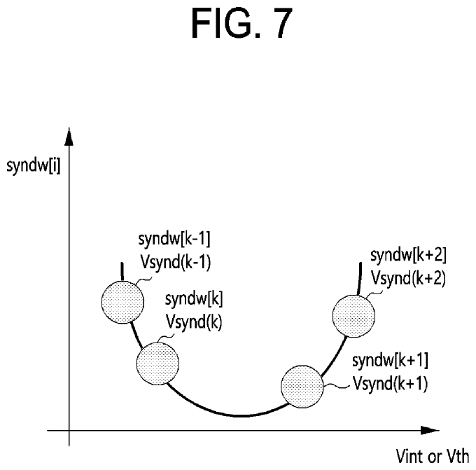

A step S551a of determining a second optimal read voltage by applying a syndrome weight according to another embodiment is described with reference to FIGS. 6 and 7.

FIG. 6 illustrates a processing process of the step S551a of determining a second optimal read voltage by applying a syndrome weight according to another embodiment. FIG. 7 illustrates two syndrome weights syndw[k] and syndw[k+1] that are included in a minimum syndrome weight variance interval.

In the step S551a of determining a second optimal read voltage by applying a syndrome weight, the read voltage setting part 150 may calculate two syndrome voltages Vsynd(k) and Vsynd(k+1) corresponding to two syndrome weights at both ends of a minimum syndrome weight variance interval. The read voltage setting part 150 may set an averaged voltage of the calculated two syndrome voltages Vsynd(k) and Vsynd(k+1) as an optimal read voltage.

The step S551a of determining a second optimal read voltage by applying a syndrome weight may include a step S5511 of calculating a syndrome, a step S5521 of calculating a syndrome weight, a step S5531 of determining whether a minimum syndrome weight variance interval is present, a step S5541 of performing a second additional read, and a step S5551 of setting a second optimal read voltage.

The step S5511 of calculating a syndrome may be a step of calculating, by the read voltage setting part 150, a syndrome synd(i) for the second read data.

The step S5521 of calculating a syndrome weight may be a step of setting, by the read voltage setting part 150, the number of “1s” that are included in the calculated syndrome as a syndrome weight syndw[i].

The step S5531 of determining whether a minimum syndrome weight variance interval is present may be a step of determining, by the read voltage setting part 150, whether the syndrome weights syndw[i] have a minimum syndrome weight variance interval.

The minimum syndrome weight variance interval may include a minimum syndrome weight. The minimum syndrome weight variance interval may include the two syndrome weights syndw[k] and syndw[k+1]. The syndrome weight syndw[k] may have a smaller value than a previous syndrome weight syndw[k−1]. The syndrome weight syndw[k+1] may have a greater value than the syndrome weight syndw[k].

The step S5541 of performing a second additional read may be performed when a minimum syndrome weight variance interval is not present.

In the step S5541 of performing a second additional read, the read voltage setting part 150 may select two syndrome voltages Vsynd(k−1) and Vsynd(k+2) that are adjacent to both ends of the minimum syndrome weight variance interval, respectively. The read operation controller 130 may obtain additional second read data by performing additional reads using the two syndrome voltages Vsynd(k−1) and Vsynd(k+2), respectively. The read voltage setting part 150 may calculate syndrome weights syndw[k−1] and syndw[k+2] for the two syndrome voltages Vsynd(k−1) and Vsynd(k+2) in the second read data including additional second read data. The read voltage setting part 150 may calculate a first syndrome weight difference between the calculated syndrome weight syndw[k−1] and the adjacent syndrome weight syndw[k]. The read voltage setting part 150 may calculate a second syndrome weight difference between the calculated syndrome weight syndw[k+2] and the adjacent syndrome weight syndw[k+1]. The read voltage setting part 150 may select a syndrome weight having a smaller value as the additional syndrome weight syndw[k+2] by comparing the first syndrome weight difference and the second syndrome weight difference.

After the step S5541 of performing a second additional read is performed, the process may return to the step S5531 of determining whether a minimum syndrome weight variance interval is present.

After including the additional syndrome weight in syndrome weights that have been previously calculated, the read voltage setting part 150 may determine whether a minimum syndrome weight variance interval is present again.

When the minimum syndrome weight variance interval is present as the results of performing the step S5531 of determining whether a minimum syndrome weight variance interval is present, the read voltage setting part 150 may perform the step S5551 of setting a second optimal read voltage by using a syndrome weight.

However, if the minimum syndrome weight variance interval is not present, the process may be performed again from the step S5541 of performing a second additional read.

The step S551 of determining a first optimal read voltage may be a step of determining, by the read voltage setting part 150, an optimal read voltage by using the minimum syndrome weight variance interval. The read voltage setting part 150 may calculate two syndrome voltages Vsynd(k) and Vsynd(k+1) at both ends of the minimum syndrome weight variance interval. The read voltage setting part 150 may set an averaged voltage of the calculated two syndrome voltages Vsynd(k) and Vsynd(k+1) as an optimal read voltage.

Steps S552 and S552a of determining third and fourth optimal read voltages and step S553 or S553a of determining fifth and sixth optimal read voltages, which will be described hereinafter, may be steps of improving the accuracy of an optimal read voltage.

In the steps S552 and S552a of determining third and fourth optimal read voltages and the step S553 or S553a of determining fifth and sixth optimal read voltages, an optimal read voltage is determined based on a minimum error bit variance or minimum syndrome weight that is predicted by applying quadratic regression.

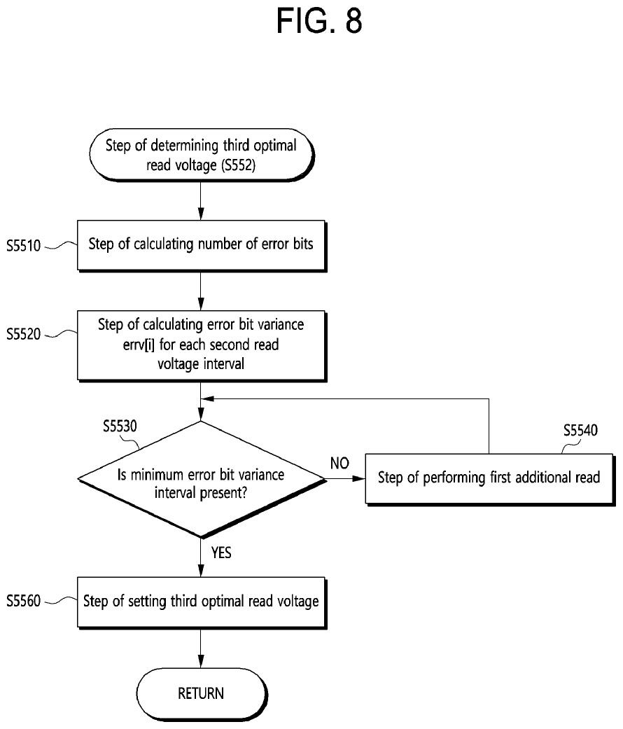

FIG. 8 illustrates a processing process of the step S552 of determining a third optimal read voltage as an optimal read voltage by predicting a minimum error bit variance by quadratic regression. FIG. 9 illustrates that an optimal read voltage Vop is determined by the step S552 of determining a third optimal read voltage.

The minimum error bit variance may be obtained by quadratic regression of two error bit variances errv[K] and errv[k+1] at both ends of a minimum error bit variance interval and an additional error bit variance.

The step S552 of determining a third optimal read voltage may include a step S5510 of calculating the number of error bits, a step S5520 of calculating an error bit variance, a step S5530 of determining whether a minimum error bit variance interval is present, a step S5540 of performing a fifth additional read, and a step S5560 of setting a third optimal read voltage.

The step S5510 of calculating the number of error bits, the step S5520 of calculating an error bit variance, the step S5530 of determining whether a minimum error bit variance interval is present, and the step S5540 of performing a first additional read are the same as the step S5510 of calculating the number of error bits, the step S5520 of calculating an error bit variance, the step S5530 of determining whether a minimum error bit variance interval is present, and the step S5540 of performing a first additional read in FIG. 4, respectively, and thus detailed descriptions thereof are omitted.

In the step S5560 of setting a third optimal read voltage, the read voltage setting part 150 may calculate a minimum error bit variance by applying quadratic regression to two error bit variances errv[k] and errv[k+1] at both ends of the minimum error bit variance interval and an additional error bit variance errv[k+2], and may then set an optimal read voltage.

The read voltage setting part 150 may obtain second read data for each second read voltage by performing an additional read using two second read voltages that are adjacent to both sides of the minimum error bit variance interval, respectively. The read voltage setting part 150 may calculate the number of error bits and an error bit variance by the two second read voltages from the second read data. The read voltage setting part 150 may set an error bit variance having a smaller value, among the calculated error bit variances, as an additional error bit variance. In FIG. 9, the additional error bit variance may be errv[k+2].

The read voltage setting part 150 may calculate a minimum error bit variance by performing quadratic regression on the two error bit variances errv[k] and errv[k+1] and the additional error bit variance errv[k+2]. The quadratic regression may be to derive a quadratic function of a parabola illustrated in FIG. 9 and to find a minimum point by using the three error bit variances.

The read voltage setting part 150 may set, as an optimal read voltage Vop, an error bit variance voltage corresponding to the minimum error bit variance.

The step S552 of determining a third optimal read voltage may be a step of determining an optimal read voltage by calculating a minimum syndrome weight by quadratic regression.

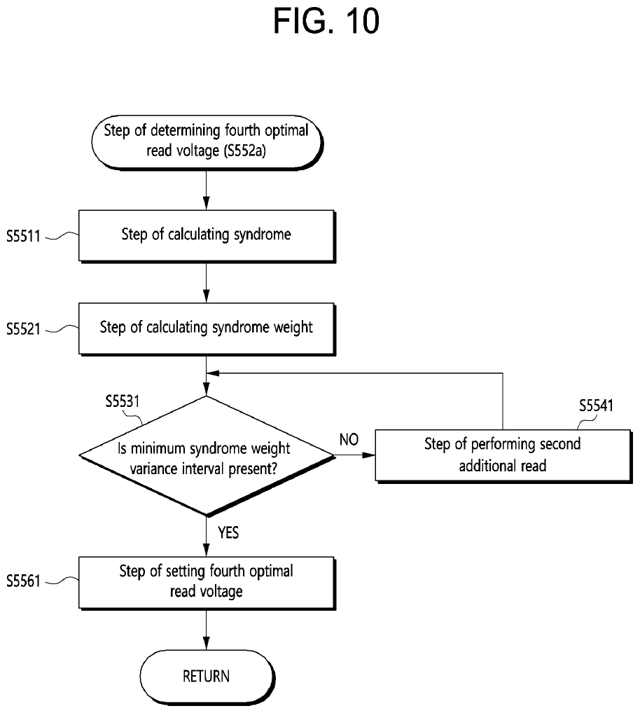

FIG. 10 illustrates a processing process of the step S552a of determining a fourth optimal read voltage as an optimal read voltage by calculating a minimum syndrome weight by quadratic regression. FIG. 11 illustrates that the minimum syndrome weight is calculated by quadratic regression.

The step S552a of determining a fourth optimal read voltage may include a step S5511 of calculating a syndrome, a step S5521 of calculating a syndrome weight, a step S5531 of determining whether a minimum syndrome weight variance interval is present, a step S5541 of performing a second additional read, and a step S5561 of setting a fourth optimal read voltage.

The step S5511 of calculating a syndrome, the step S5521 of calculating a syndrome weight, the step S5531 of determining whether a minimum syndrome weight variance interval is present, and the step S5541 of performing a second additional read are the same as the steps included in the step S551a of determining a second optimal read voltage by applying a syndrome weight in FIG. 6, and thus detailed descriptions thereof are omitted.

In the step S552a of determining a fourth optimal read voltage, the step S5561 of setting a fourth optimal read voltage may be a step of setting, by the read voltage setting part 150, an optimal read voltage based on a minimum syndrome weight that is predicted by applying quadratic regression.

Specifically, the read voltage setting part 150 may calculate a syndrome and a syndrome weight by using two second read voltages that are adjacent to the minimum syndrome weight variance interval, and may set a syndrome weight having a smaller value, among the calculated syndrome weights, as an additional syndrome weight. In FIG. 11, the additional syndrome weight may be syndw[k+2].

The read voltage setting part 150 may calculate a minimum syndrome weight by performing quadratic regression on two syndrome weights syndw[i] and syndw[i+1] at both ends of the minimum syndrome weight variance interval and an additional syndrome weight syndw[i+2]. The quadratic regression may be to derive a quadratic function indicative of the three error bit variances and to find a minimum syndrome weight.

The read voltage setting part 150 may set a voltage corresponding to the minimum syndrome weight as an optimal read voltage Vop.

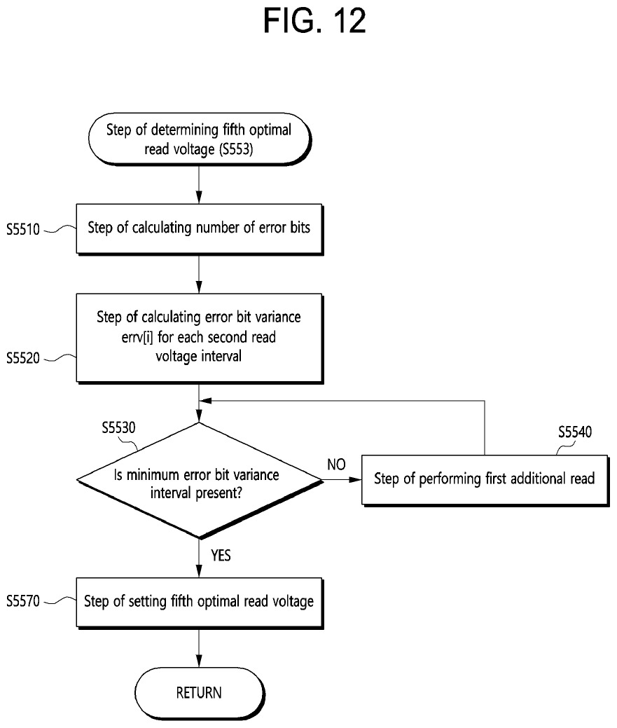

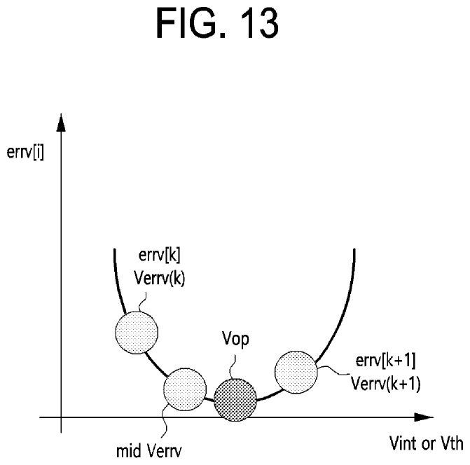

FIG. 12 illustrates a processing process of the step S553 of determining a fifth optimal read voltage as an optimal read voltage by predicting a minimum error bit variance by quadratic regression. FIG. 13 illustrates that the minimum error bit variance is predicted by applying quadratic regression.

In the step S553 of determining a fifth optimal read voltage in FIGS. 12 and 13, an optimal read voltage may be determined by performing quadratic regression using an additional error bit variance disposed within the minimum error bit variance interval.

The step S553 of determining a fifth optimal read voltage may include a step S5510 of calculating the number of error bits, a step S5520 of calculating an error bit variance, a step S5530 of determining whether a minimum error bit variance interval is present, a step S5540 of performing a first additional read, and a step S5570 of setting a fifth optimal read voltage.

The step S5510 of calculating the number of error bits, the step S5520 of calculating an error bit variance, the step S5530 of determining whether a minimum error bit variance interval is present, and the step S5540 of performing a first additional read are the same as the steps included in the processing process of FIG. 4, and thus detailed descriptions thereof are omitted.

In the step S5570 of setting a fifth optimal read voltage, the read voltage setting part 150 may select, as an additional read voltage, a middle error bit variance voltage mid Verrv of error bit variance voltages Verrv(k) and Verrv(k+1) at both ends of the minimum error bit variance interval.

The read operation controller 130 may obtain additional second read data by performing a second read using an additional read voltage.

The read voltage setting part 150 may calculate an additional error bit variance for the additional read voltage from the additional second read data.

The read voltage setting part 150 may find a minimum error bit variance by performing quadratic regression on the three error bit variances, including two error bit variances at both ends of the minimum error bit variance interval and the additional error bit variance. The quadratic regression may be to derive a quadratic function of a parabola illustrated in FIG. 13 and to find a minimum error bit variance by using the three error bit variances.

The read voltage setting part 150 may set, as an optimal read voltage Vop, a voltage corresponding to the minimum error bit variance.

The step S553 of determining a fifth optimal read voltage may be a step of determining an optimal read voltage based on a minimum syndrome weight that is predicted by quadratic regression.

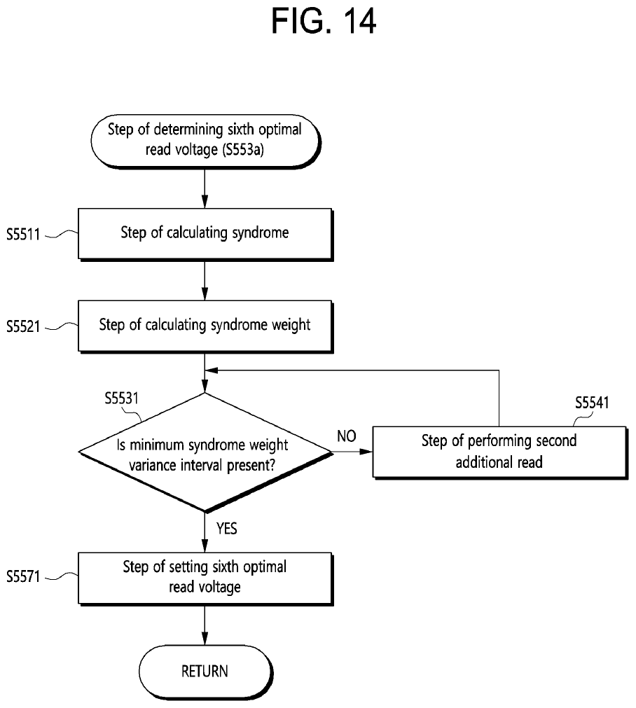

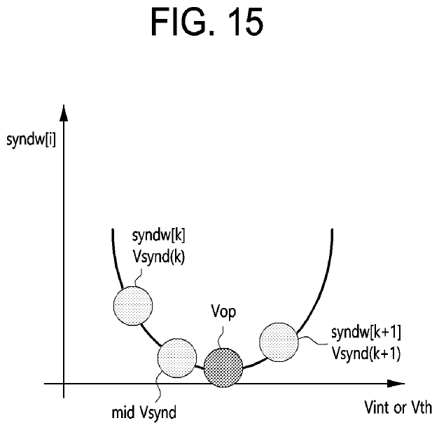

FIG. 14 illustrates the step S553a of determining a sixth optimal read voltage as an optimal read voltage based on a minimum syndrome weight that is predicted by applying quadratic regression. FIG. 15 illustrates that the minimum syndrome weight is predicted by applying quadratic regression.

The step S553a of determining a sixth optimal read voltage may include a step S5511 of calculating a syndrome, a step S5521 of calculating a syndrome weight, a step S5531 of determining whether a minimum syndrome weight variance interval is present, a step S5541 of performing a second additional read, and a step S5571 of setting a sixth optimal read voltage.

The step S5511 of calculating a syndrome, the step S5521 of calculating a syndrome weight, the step S5531 of determining whether a minimum syndrome weight variance interval is present, and the step S5541 of performing a second additional read are the same as the steps included in the processing process of FIG. 6, and thus detailed descriptions thereof are omitted.

In the step S5571 of setting a sixth optimal read voltage, the read voltage setting part 150 may extract syndrome voltages at both ends of the minimum syndrome weight variance interval. The read voltage setting part 150 may select an averaged voltage of the extracted syndrome voltages as an additional read voltage. In FIG. 15, the additional read voltage may be mid Vsynd. The read operation controller 130 may generate additional second read data by performing an additional read using an additional read voltage.

The read voltage setting part 150 may calculate an additional syndrome and additional syndrome weight corresponding to the additional read voltage from the additional second read data.

The read voltage setting part 150 may find a minimum syndrome weight by performing quadratic regression on three syndrome weights, including two syndrome weights at both ends of the minimum syndrome weight variance interval and the additional syndrome weight. The quadratic regression may be to derive a quadratic function of a parabola illustrated in FIG. 15 by using the three syndrome weight and to find a minimum syndrome weight corresponding to a minimum point of the quadratic function.

The read voltage setting part 150 may set, as an optimal read voltage Vop, a syndrome voltage corresponding to the minimum syndrome weight.

According to an embodiment, an optimal read voltage can be searched for in relation to an error bit variance of a second read voltage interval without searching for the optimal read voltage up to the limit of left and right CDPs through repeated additional reads. Accordingly, the number of reads for searching for an optimal read voltage can be reduced or minimized.

Effects of the present technology are not limited to the aforementioned effects, and other effects not described above may be evidently understood by those skilled in the art from the following description.

The embodiments described in this specification and the accompanying drawings merely illustrate some of the technical spirit included in the present technology. Accordingly, the embodiments disclosed in this specification are not intended to limit the technical spirit of the present technology, but illustrate the technical spirit of the present technology. Accordingly, it is evident that the scope of the technical spirit of the present technology is not restricted by the embodiments. All modified examples and detailed embodiments which may be inferred by those skilled in the art without departing from the scope of the technical spirit included in the specification and drawings of the present technology should be construed as being included in the scope of rights of the present technology.

What is claimed is:

1. An operating method of a semiconductor storage device, the method comprising:
selecting at least three second read voltages in relation to a first read voltage when a first read for a memory device is a fail;
obtaining second read data by using the second read voltages; and
determining an optimal read voltage based on a minimum error bit variance interval comprising a minimum error bit variance that is included in the second read data.

2. The operating method of claim 1, wherein determining the optimal read voltage is performed when error correction decoding for the second read data is a fail.

3. The operating method of claim 1, wherein determining the optimal read voltage comprises:
calculating a number of error bits for each second read voltage, which are included in the second read data;
calculating an error bit variance for each second read voltage interval by calculating a difference between the numbers of error bits for each of the second read voltages that are adjacent to each other;
determining whether the minimum error bit variance interval comprising two consecutive error bit variances comprising the minimum error bit variance is present; and
setting the optimal read voltage based on two error bit variances at both ends of the minimum error bit variance interval when the minimum error bit variance interval is present.

4. The operating method of claim 3, wherein setting the optimal read voltage comprises setting, as the optimal read voltage, an average voltage of two error bit variance voltages corresponding to the two error bit variances.

5. The operating method of claim 3, wherein setting the optimal read voltage comprises:
predicting the minimum error bit variance by quadratic regression using the two error bit variances at both ends of the minimum error bit variance interval and an additional error bit variance; and
setting an error bit variance voltage of the predicted minimum error bit variance as the optimal read voltage.

6. The operating method of claim 5, wherein the additional error bit variance is the smaller error bit variance among two error bit variances that are disposed at both side of the minimum error bit variance interval outside the minimum error bit variance interval.

7. The operating method of claim 5, wherein the additional error bit variance comprises two error bit variances generated by calculating a difference between a number of error bits that are included in additional read data obtained by using an additional read voltage and a number of error bits that are included in second read data obtained by a second read using the two error bit variance voltages.

8. The operating method of claim 3, further comprising performing one additional read using an error bit variance voltage having the smaller error bit variance among two error bit variances that are adjacent to both ends of the minimum error bit variance interval, when the minimum error bit variance interval is not present as results of determining whether the minimum error bit variance interval is present,
wherein the operating method is performed again from determining whether the minimum error bit variance interval is present after performing the one additional read.

9. The operating method of claim 1, wherein:
the error bit variance is a syndrome weight for a syndrome of the second read data obtained for each second read voltage, and
the minimum error bit variance interval is a minimum syndrome weight variance interval.

10. A semiconductor storage device comprising:
a memory device comprising memory cells; and
a memory controller configured to determine an optimal read voltage for the memory device,
wherein the memory controller is configured to
select at least three second read voltages in relation to a first read voltage when a first read for the memory device is a fail,
obtain second read data by performing a second read using the selected second read voltages, and
determine an optimal read voltage based on a minimum error bit variance interval comprising a minimum error bit variance that is included in the second read data.

11. The semiconductor storage device of claim 10, wherein the memory controller comprises:
a read operation controller configured to select the at least three second read voltages in relation to the first read voltage when the first read is a fail during a read operation for the memory cells and to obtain the second read data by performing the second read using the selected second read voltages;
a fail detector configured to determine whether the read operation of the read operation controller is a pass or a fail; and
a read voltage setting part configured to determine the optimal read voltage based on two error bit variances at both ends of the minimum error bit variance interval comprising the minimum error bit variance that is included in the second read data.

12. The semiconductor storage device of claim 11, wherein the fail detector is configured to determine that the first read or the second read is a fail, when a number of error bits that are included in first read data obtained by the first read or a number of error bits that are included in the second read data obtained by the second read is greater than a number of bits capable of being corrected by an error correction decoder.

13. The semiconductor storage device of claim 11, wherein the read voltage setting part is configured to perform the determination of the optimal read voltage when the second read is determined to be a fail by the fail detector.

14. The semiconductor storage device of claim 11, wherein the read voltage setting part is configured to:
calculate a number of error bits for each of the second read voltages that are included in the second read data,
calculate an error bit variance for each second read voltage interval by calculating a difference between the numbers of error bits for each of the second read voltages that are adjacent to each other, and
determine the optimal read voltage based on two error bit variances at both ends of the minimum error bit variance interval when the minimum error bit variance interval comprising two consecutive error bit variances comprising the minimum error bit variance is present.

15. The semiconductor storage device of claim 14, wherein the read voltage setting part is configured to set, as the optimal read voltage, an averaged voltage of two error bit variance voltages corresponding to the two error bit variances.

16. The semiconductor storage device of claim 14, wherein the read voltage setting part is configured to:
predict the minimum error bit variance by quadratic regression using the two error bit variances at both ends of the minimum error bit variance interval and an additional error bit variance, and
set an error bit variance voltage of the predicted minimum error bit variance as the optimal read voltage.

17. The semiconductor storage device of claim 16, wherein the additional error bit variance is the smaller error bit variance among two error bit variances that are disposed at both side of the minimum error bit variance interval outside the minimum error bit variance interval.

18. The semiconductor storage device of claim 16, wherein:
the additional error bit variance comprises two error bit variances generated by calculating a difference between a number of error bits that are included in additional read data obtained by using an additional read voltage and a number of error bits that are included in second read data obtained by a second read using the two error bit variance voltages, and
the second additional read voltage is an averaged voltage of error bit variance voltages of the two error bit variances at both ends of the minimum error bit variance interval.

19. The semiconductor storage device of claim 15, wherein the read voltage setting part is configured to:
perform one additional read using an error bit variance voltage having a smaller error bit variance, among error bit variances that are disposed in a direction in which the second read voltage is decreased and a direction in which the second read voltage is increased, respectively, when the minimum error bit variance interval is not present, and
determine whether the minimum error bit variance interval is present again.

20. The semiconductor storage device of claim 10, wherein:
the error bit variance is a syndrome weight for a syndrome of the second read data obtained for each second read voltage, and
the minimum error bit variance interval is a minimum syndrome weight variance interval.
